(19) United States
(12) Patent Application Publication
(10) Pub. No.: US 2014/0110843 A1
(43) Pub. Date: Apr. 24, 2014

(54) Semiconductor Unit with Submount for Semiconductor Device

(71) Applicant: IIPG Photonics Corporation, Oxford, MA (US)

(72) Inventors: Alexander Ovtchinnikov, Worcester, MA (US); Alexey Komissarov, Charlton, MA (US); Igor Berishev, Holden, MA (US); Svetlan Todorov, Shrewsbury, MA (US)

(73) Assignee: IIPG Photonics Corporation, Oxford, MA (US)

(21) Appl. No.: 14/143,444

(22) Filed: Dec. 30, 2013

(30) Foreign Application Priority Data
Jun. 11, 2011 (US) PCT/US2011/040901

(51) Int. Cl. H01L 23/00

(52) U.S. Cl. CPC H01L 24/32; H01L 24/27
USPC 257/739; 438/612

(57) ABSTRACT

A semiconductor unit includes a submount and a chip coupled to the submount. The submount is configured with a base and a plurality of layers between the base and the chip. One of the layers, a heat-spreading electro-conducting sliver (“Ag”) layer, is deposited atop the base. The thickness of the Ag layer is selected so that a cumulative coefficient of thermal expansion of the submount substantially matches that one of the chip. Coupled to the active zone of the chip is a stress-dumping layer made from elastic malleable materials.

### BACKGROUND OF THE DISCLOSURE

1. Technical Field

The present invention relates to a semiconductor unit incorporating a submount, and more particularly to a submount for supporting a semiconductor device.

2. Known Art

FIG. 1 illustrates rather a simplified, typical semiconductor unit having a semiconductor device 8 mounted on a submount 1 as shown in FIG. 1. The submount 1 comprises a base 2, such as a ceramic substrate, a relatively thick thermo- and electro-conducting layer 4 which typically has a thickness up to several microns and a solder layer 6. The layer 4 is configured to spread out heat, as shown by arrows, which is generated during the use of a semiconductor device or chip 8. Typically, layer 4 is made from gold often rendering the semiconductor unit rather cost-ineffective.

The layer 4 has two important functions. One of the functions includes bonding base 2 and chip 8 while spreading out heat from the chip's operation. The other function includes providing electro-conductivity between the contacts, as known by one of ordinary skill in the art.

The temperatures reached during the operation of chip 8 are typically high. Since thermo-conductivity of base 2 is lower than that one of adjacent Au metal layer 4, cyclical temperature changes cause substantial stresses on device 7. These stresses may lower the reliability of device 7.

Turning again to FIG. 1, typically an electrical circuitry allows current 1 to flow from a plus potential through Au layer 4 and P-N junction to a minus potential. The lower the resistivity of layer 4, the less resistive heating, the higher the power conversion efficiency (“PCE”) of chip 8.

The electrode gold (Au) layer 4 facilitates the severity of elevated temperatures during the operation of the unit by spreading the generated heat over a portion of surface while guiding the heat through base 2 towards a heat sink. However, the thermo- and electro-conductive surface of Au layer 4 is rather small which impedes the heat spreading process. Besides, the electrical resistivity of Au layer is appreciable.

It is therefore desirable to manufacture a cost effective semiconductor unit.

It is further desirable to configure a semiconductor unit of the type disclosed herein which can efficiently spread heat generated during manufacturing and operation of the unit.

It is still further desirable to configure a semiconductor unit of the type disclosed herein which has a high power conversion efficiency.

It is also desirable to provide a process for manufacturing a semiconductor unit distinguished by its thermal efficiency and low manufacturing costs.

### SUMMARY OF THE DISCLOSURE

The above articulated needs are met by a semiconductor unit and a method for configuring the unit as disclosed hereinbelow. In accordance with one of salient features of the disclosures, a typically relatively thick gold (Au) layers is substantially replaced with a silver (Ag) layer. The use of an Ag layer translates into substantial cost savings and enhanced performance and reliability of the semiconductor unit through the reduced thermal loading, all of which lead to a high power conversion efficiency (“PCE”).

Typically materials of different layers composing a submount of semiconductor unit have respective coefficients of thermal expansion (“CTE”) which differ from one another and from materials used for manufacturing a chip. As a rule, the base of semiconductor units has a CTE lower than that one of the Ag layer. Thus the layers of the submount may be configured so that their cumulative CTE substantially matches the CTE of the material of the chip. Once this condition is met, the generation of mechanical stresses is considerably minimized.

In accordance with one embodiment of the disclosure configured to minimize stresses, the inventive unit is configured with a controlled thickness of Ag layer which is deposited atop the base by any known process, such as electroplating. The desired thickness of the Ag layer is determined so that a cumulative CTE of the submount substantially matches that one of material used for configuring a chip.

A further embodiment includes a layer of plastic/malleable material deposited between the chip and Ag layer. The soft material layer is configured so that it may reduce mechanical stresses on the chip even if the thickness of the Ag layer is arbitrary. Of course, both techniques may be combined.

### BRIEF DESCRIPTION OF THE DRAWINGS

The above and other features and advantages of the disclosed unit will become more readily apparent from the following specific description accompanied by following drawings, in which:

FIG. 1 is a diagrammatic view representative of known semiconductor unit configurations.

FIG. 2 is a diagrammatic view of the disclosed unit.

FIG. 3 is a diagrammatic view of the modified unit of FIG. 2.

FIG. 4 is an elevated view of a component of the unit of FIG. 3

### SPECIFIC DESCRIPTION

The reference will now be made in detail to the disclosed configurations. The drawings are far from precise scale and do not show well known to an artisan in semiconductor industry additional layers. The word “couple” and similar terms do not necessarily denote direct and immediate connections, but also include connections through intermediate elements.

FIG. 2 shows a structure of one of disclosed configuration of a semiconductor unit including a submount 10 and a chip 20. The latter may he selected from a 2-terminal device such as a high power laser diode light emitting diode or light-emitting diode, a 3-terminal device such as a transistor, a 4-terminal semiconductor device including, for example, a Hall effect sensor and multi-terminal semiconductor devices such as an ICs. The submount 10 comprises a base 12, a thick Ag layer 14 deposited upon base 12 and used as a heat and electro spreader, and a thin layer of hard solder 18. The Ag layer 14 may be deposited by a variety of techniques, such as electro-plating and others, and have a variety of dimensions and shapes. For example, as shown in FIG. 2, Ag layer 14 may continuously extend over base 12 at least for a length of chip 20. The use of silver effectively reduces the overall cost of a semiconductor unit if compared to the known prior art using gold.

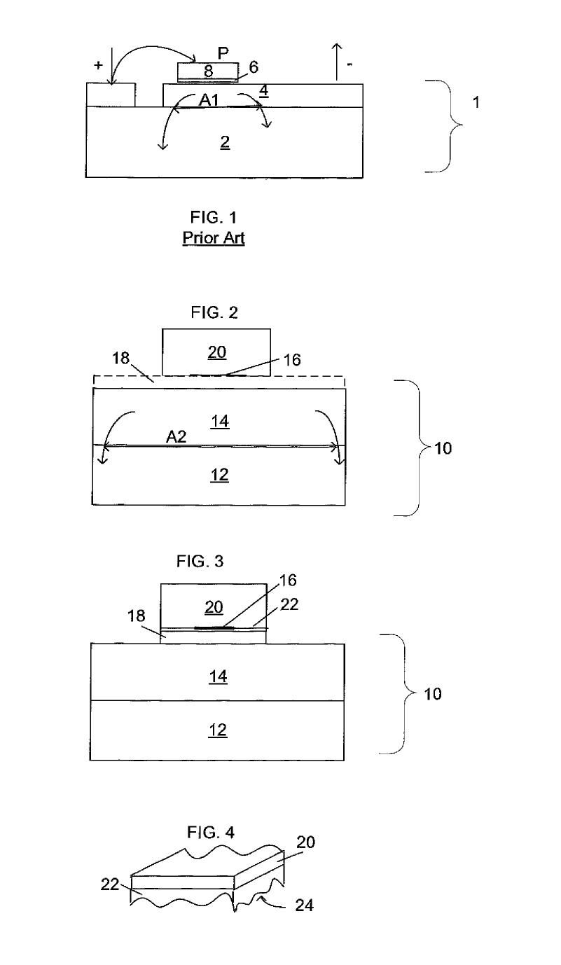

The Ag layer 14 not only renders the disclosed unit cost-effective, but it also renders the unit most thermo- and electro-efficient. The thermoconductivity of silver is higher than that of gold, whereas its electro-resistivity is lower. As known, a thermo-conducting surface is a function of material. Accordingly, the heat, which is generated when chip 20 is in use by an active zone 16, spreads out across a surface A2 of Ag layer 14 which is greater than surface A1 of Au layer 2 in FIG. 1. Therefore the area of base 12, involved in transferring the heat to a heat sink (not shown), is larger than the area of base 2 in FIG. 1 representing the known art. In fact, surface A2 of Ag layer 14, under equal conditions, is larger than a heat spreading surface of practically any metal since its thermo-conductivity is the highest among metals. The tests show than even a 20 micron thick Ag layer reduces the temperature of a p-n junction by about 10 degrees compared to the gold layer of FIG. 1 with a comparable thickness. Hence, the reliability of disclosed chip 20 is considerably enhanced.

The thickness of deposited heat-spreading and electro-conducting Ag layer 14 should be controlled since it directly correlates to a coefficient of thermal expansion of the submount components and material of chip 20. Consequently, if a cumulative coefficient of thermal expansion of submount 10 substantially matches that one of material of chip 20, mechanical stresses affecting disclosed device 20, can be substantially reduced. The following equation fairly characterizes the determination of Ag layer's thickness:

$$\frac{{\sum }_{1}^{n} KD}{{\sum }_{1}^{n} D}$$

where K is a coefficient of thermal expansion and D is a thickness of any given layer of submount 10. Accordingly, since thermal expansion coefficients for respective materials are known, it is easy to determine a thickness of Ag provided the thickness of each of the submount layers is known. Consider the following example.

A coefficient of expansion of Ag is 19.5, coefficient of base 12 which, for example is made from aluminum nitride (AlN) is 4.5 and coefficient of expansion of GaAs—exemplary material of chip 20—is 5.8. Assume further that a thickness D of base layer 12 is 300 micron. Accordingly, the thickness of Ag layer 14 should be selected so that the cumulative coefficient of expansion of submount 10 was 5.8. Using the above-disclosed equation, Ag layer 14 should have the following thickness X.

$$\frac{300 \times 4.5 ⊕ X \times 19.5}{300 ⊕ X} = 5.8$$

The Ag layer is approximately 28 microns thick. Accordingly, in the given example, the 28 micron thick Ag layer provides minimal mechanical stresses acting on chip 20.

FIG. 3 illustrates the other stress-reduction technique. The submount 10 in addition to the layers shown in FIG. 2 is configured with a soft plating layer 22 of elastic electro-conductive material which is located between chip 20 and solder 18. The layer 22 may be, for example, pure gold.

FIG. 4 illustrates an exemplary configuration of plastic layer 22 which has a textured surface 24 facing solder 18. The pattern of surface 24 is not limited and, for example, may include cylindrically, pyramidally, triangularly and other regularly- and irregularly-shaped protrusions which are spaced from one another to define respective valleys therebetween. As the unit cools down after soldering, the elastic material affected by stresses deforms. Accordingly, layer 22 is configured as a stress-dumping barrier protecting chip 20 from mechanical stresses. The use of stress-dumping layer 22 allows the chip designer to have an arbitrary thickness of Ag layer 14. Of course, a combination of Ag layer 14, whose thickness is determined in accordance with the disclosure, and elastic plating 22 may also be used for manufacturing the disclosed unit.

In summary, a thick Ag layer deposited on submount, which may be made from ceramics, metals and other suitable materials, dramatically reduces manufacturing costs of the semiconductor unit of the type disclosed herein above. Furthermore, if a thickness of Ag layer is determined in accordance with the equation, chip 20 may be protected from mechanical stresses generated during heating/cooling manufacturing stages. Finally, a specifically configured soft layer may also be sufficient to largely reduce the mechanical stresses even if the Ag layer has an arbitrary thickness.

The present disclosure is not restricted to particular configurations which are described here. It is apparent that departure from specific structures and configurations as described and shown will suggest themselves to those skilled in the art and may be used without departing from the scope of the disclosure, as defined in the following claims.

1. A semiconductor unit comprising:
a base,
a chip spaced from the base, and
a heat-spreading electro-conducting Ag layer deposited atop the base and coupled to the chip, wherein the base and the Ag layer determines a submount.

2. The semiconductor and of claim 1 further comprising a hard solder atop the Ag layer between the Ag layer and the chip.

3. The semiconductor unit of claim 2, wherein the Ag layer is configured with a thickness determined to provide a submount, which includes the base, Ag and soldering layers, with a cumulative thermo-expansion coefficient substantially matching a coefficient of thermo-expansion of the chip.

4. The semiconductor unit of claim 2 further comprising a stress-dumping layer made from elastic malleable materials and between the hard solder and an active zone of the chip.

5. The semiconductor unit of claim 4, wherein the stress-dumping layer has a textured surface next to the soldering layer.

6. The semiconductor unit of claim 5, wherein the textured surface of the stress-dumping layer is configured with spaced protrusions.

7. The semiconductor unit of claim 1, wherein the chip is selected from the group consisting of two-, three-, four-terminal and multi-terminal semiconductor devices and a combination thereof.

8. The semiconductor unit of claim 7, wherein the two-terminal device comprises a high power laser diode.

9. A method of manufacturing a semiconductor unit comprising:
providing a base,
depositing a heat-Spreading electro-conducting Ag layer atop the base; and
soldering the base and Ag layers to a chip at elevated temperatures.

10. The method of claim 9 further comprising providing a hard soldering layer between the Ag layer and chip.

11. The method of claim 10 further comprising configuring the Ag layer with a thickness providing a submount, which includes the base, Ag and soldering layers, with a cumulative thermo-expansion coefficient substantially matching a coefficient of thermo-expansion of the chip, wherein the matching coefficients provide for reduced mechanical stresses acting upon the chip.

12. The method of claim 10 further comprising providing an elastic stress-dumping layer from malleable material between the soldering layer and an active zone of the chip.

13. The method of claim 12 further comprising providing the stress-dumping layer with a textured surface facing away from an active zone of the chip.
